(19) United States
(12) Patent Application Publication
(10) Pub. No.: US 2017/0213966 A1
(43) Pub. Date: Jul. 27, 2017

(54) METHOD AND SYSTEM FOR FORMING FILM

(71) Applicant: BOE TECHNOLOGY GROUP CO., LTD., Beijing (CN)

(72) Inventors: Huifeng WANG, Beijing (CN); Ze LIU, Beijing (CN)

(73) Assignee: BOE Technology Group Co., Ltd., Beijing (CN)

(21) Appl. No.: 15/322,145

(22) PCT Filed: Sep. 24, 2015
(86) PCT No.: PCT/CN2015/090501

§ 371 Date: Dec. 26, 2016

(30) Foreign Application Priority Data
Jun. 26, 2015 (CN) 201510364451.8

(51) Int. Cl. H01L 51/00; B41J 2/01; H01L 51/56; C23C 14/58

(52) U.S. Cl. CPC H01L 51/0005; C23C 14/58; B41J 2/01; H01L 51/56; H01L 51/5012

(57) ABSTRACT

The present disclosure provides in some embodiments a method and a system for forming a film. The method includes forming ink droplets on a base substrate, wherein each of the ink droplets includes a first solvent and a film material dissolved in the first solvent, subjecting the ink droplets to a solvent homogenizing distribution process, and evaporating the first solvent in the ink droplets to form the film after the ink droplets have been subjected to the solvent homogenizing distribution process.

### CROSS-REFERENCE TO RELATED APPLICATION

The present application claims a priority of Chinese Patent Application No. 201510364451.8 filed on Jun. 26, 2015, the disclosure of which is incorporated herein by reference in its entirety.

### TECHNICAL FIELD

The present disclosure relates to the technical field of forming a film, in particular to a method and a system for forming a film.

### BACKGROUND

Organic Light-Emitting Diode (OLED) display device are becoming more and more popular in the display field due to its advantages such as active luminescence, fast response, wide viewing angle, high brightness, rich colors, and being slim and thin. Ink Jet Print (IJP) process is one of various processes of forming a film for the OLED, and is a new technology capable of depositing a patterned film in a direct manner.

During the IJP process, it is typically to dissolve a material for an OLED function layer as a solution in a particular solvent, so as to obtain the ink for the IJP, wherein the particular solvent may include one or more organic compounds such as ethylene glycol, glycerol, toluene, mesitylene, anisole methoxybenzene and cyclohexylbenzene. Then, as shown in FIG. 1, an ink 02 is printed onto a base substrate 03 by an ink jet printer 01, and then the base substrate 03 on which the ink 02 is printed is subjected to processes such as drying and baking, so as to enable the solvent in the ink to be completely volatilized, and finally deposit an OLED film consisted of a material for the OLED function layer on the base substrate.

However, in the above IJP process, a size of a head of the ink jet printer 01 is much less than that of the base substrate 03. Thus, the ink jet printer 01 has to execute a printing process many times to enable the ink 02 to cover whole of the base substrate 03. As a result, as shown in FIG. 2, densities of ink droplets distributed on the whole base substrate are non-uniform due to a difference between a time of volatilizing ink droplets and a time of volatilizing adjacent second ink droplets on the base substrate as well as a difference between an atmosphere where some ink droplets are sprayed at one time and another atmosphere where some other ink droplets are sprayed at another one time, so that border traces 100 appears on the base substrate, which finally causes non-uniform of the OLED film deposited on the base substrate, and adversely affects luminance uniformity of the OLED display device.

### SUMMARY

An object of the present disclosure is to provide a method and a system for forming a film, so as to improve the uniformity of the film which is adversely affected by the above time difference and the above atmosphere difference, and thus improve display quality of the display device.

For achieving the above object, the embodiments of present disclosure provides the following technical solutions.

In a first aspect, the present disclosure provides in some embodiments a method for forming a film including: forming ink droplets on a base substrate, wherein each of the ink droplets includes a first solvent and a film material dissolved in the first solvent; subjecting the ink droplets to a solvent homogenizing distribution process; and evaporating the first solvent in the ink droplets to form the film after the ink droplets have been subjected to the solvent homogenizing distribution process.

Optionally, the film includes one or more of a hole transport layer, an organic light-emitting layer, a hole injection layer, an electron injection layer and an electron transport layer for an organic light-emitting diode.

Optionally, the step of subjecting the ink droplets to the solvent homogenizing distribution process includes: placing the base substrate on which the ink droplets are formed into a solvent bin, wherein the solvent bin is of a sealable structure.

Optionally, a second solvent in a gaseous state is distributed uniformly in the solvent bin, wherein composition of the second solvent is same as that of the first solvent, or in the case that the first solvent includes two or more components, the second solvent includes any one or more of the components of the first solvent.

Optionally, the solvent bin includes a storage structure configured to store the second solvent.

Optionally, after the step of placing the base substrate on which the ink droplets are formed into the solvent bin, the method further includes: heating the solvent bin.

Optionally, the solvent bin is heated at such a temperature that a saturated vapor pressure is achieved in the solvent bin by the first solvent and the second solvent.

In a second aspect, the present disclosure provides in some embodiments a system for forming a film, including a printing device, a drying device and a solvent equilibrium device, wherein the printing device is configured to form ink droplets on a base substrate, wherein each of the ink droplets includes a first solvent and a film material dissolved in the first solvent; the solvent equilibrium device is configured to subject the ink droplets to a solvent homogenizing distribution process; and the drying device is configured to evaporate the first solvent in the ink droplets to form the film after the ink droplets have been subjected to the solvent homogenizing distribution process.

Optionally, the solvent equilibrium device includes a solvent bin, the solvent bin is of a sealable structure, and configured to accommodate the base substrate on which the ink droplets are formed, and isolate the base substrate from the outside.

Optionally, the solvent bin includes a storage structure configured to store the second solvent, composition of the second solvent is same as that of the first solvent, or in the case that the first solvent includes two or more components, the second solvent includes any one or more of the components of the first solvent.

Optionally, the storage structure is arranged above the base substrate and not in contact with the base substrate.

Optionally, a solvent injection member is arranged on the storage structure, the solvent injection member is configured to inject the second solvent into the storage structure.

Optionally, the system further includes a heating device, the heating device is configured to heat the solvent bin.

Optionally, the system further includes a transport device, the transport device is configured to transport the base substrate on which the ink droplets are formed into the solvent bin.

The present disclosure provides in some embodiments a method and a system for forming a film, wherein ink droplets are formed on a base substrate, and then the ink droplets on the base substrate are subjected to a solvent homogenizing distribution process, so that densities of the ink droplets distributed on the base substrate tend to be uniform. Further, when a first solvent in the ink droplets is evaporated, a film with a more uniform thickness may be formed due to the uniformity of the densities of the ink droplets distributed on the base substrate. As a result, it is at least partially prevented the border traces on the base substrate that were generated in the printing process due to the printing time difference and the ink droplets atmosphere difference in the related art from being generated, so as to improve the uniformity of the film, and thus improve the display quality of the display device.

### BRIEF DESCRIPTION OF THE DRAWINGS

In order to illustrate the technical solutions of the present disclosure or the related art in a clearer manner, the drawings desired for the embodiments will be described briefly hereinafter. Obviously, the following drawings merely relate to some embodiments of the present disclosure, and based on these drawings, a person skilled in the art may obtain the other drawings without any creative effort.

FIG. 1 a schematic view showing an operating principle of a ink jet printer in the related art;

FIG. 2 is a schematic view showing a distribution of ink droplets on a base substrate after a IJP process in the related art;

FIG. 3 is a flow chart showing a method for forming a film according to an embodiment of the present disclosure;

FIG. 4 is another flow chart showing a method for forming a film according to an embodiment of the present disclosure;

FIG. 5 is a schematic view showing ink droplets distributed on the base substrate and not subjected to a solvent homogenizing distribution process in the related art;

FIG. 6 is a schematic view showing ink droplets distributed on the base substrate in the film forming method according to an embodiment of the present disclosure;

FIG. 7 is a schematic view showing a system for forming a film according to an embodiment of the present disclosure;

FIG. 8 is a schematic view showing a solvent bin according to an embodiment of the present disclosure;

FIG. 9 is another schematic view showing a solvent bin according to an embodiment of the present disclosure; and

FIG. 10 is another schematic view showing a system for forming a film according to an embodiment of the present disclosure.

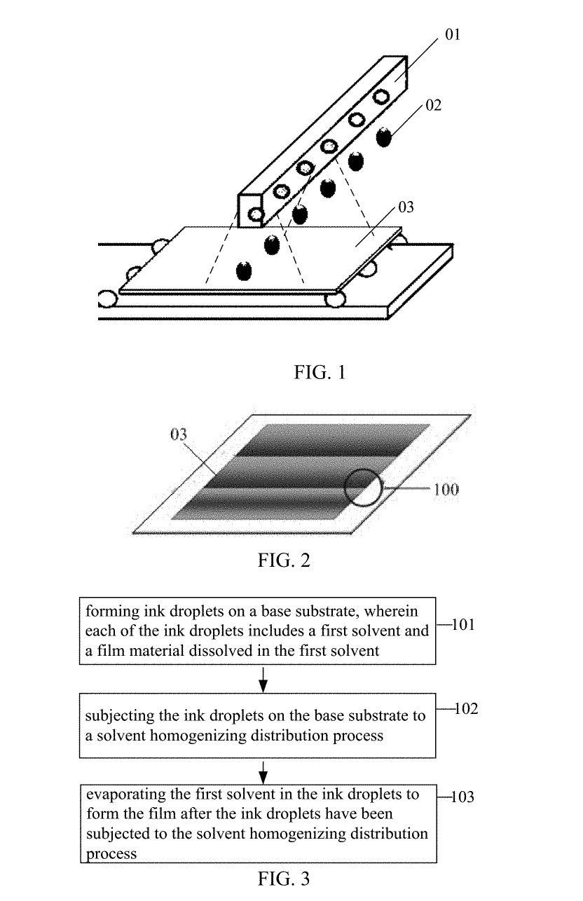

### DETAILED DESCRIPTION

In the following description, specific details such as particular system structure, interface and technique, are described, which are for illustration purpose only to provide a thoroughly understanding of the present disclosure, but shall not be used to limit the scope of the present disclosure. However, it should be noted that the present disclosure may be implemented by another embodiment without such details. In other instances, a details description of the known device, circuit and method are omitted herein, so as to prevent the unnecessary details from obscuring the principle of the present disclosure.

In addition, the terms “first” and “second” are for illustration purpose only, and shall not be understood to represent or imply an relative importance or implicitly indicate the number of the targeted technical features. Thus, a feature defined by “first” or “second” may explicitly or implicitly includes one or more of such features. In the present disclosure, unless otherwise defined, “a plurality” indicates two or more.

### Embodiment 1

When ink droplets are sprayed on a base substrate by an ink jet printer, since the ink droplets includes a film material, a film may be deposited on the base substrate by drying and baking the base substrate on which the ink droplets are formed. For example, when the film material is a material for an OLED function layer, the formed film is an OLED film. In the following embodiment, the present disclosure is described by taking the OLED film as an example. However, it should be noted that, such filming forming method may also be adapted to form other kinds of film, such as an organic film in an array base substrate, or a film in a Thin Film Transistor (TFT), which is not particularly defined herein.

A printing range of the ink jet printer is limited in every printing process, and thus the ink jet printer has to operate a plurality of times to distribute the ink droplets on the whole surface of the base substrate. Further, the film material in the ink droplets is less volatile due to its high boiling point, while the first solvent in the ink droplets is volatile due to its low boiling point. In actual printing, an atmosphere where some ink droplets are sprayed at one time may be different from another atmosphere where some other ink droplets are sprayed at another one time, and the first solvent in the ink droplets sprayed at a earlier time may be more evaporated than that in the ink droplets sprayed at a later time. As a result, the densities of the ink droplets distributed on the whole base substrate may be non-uniform, so that border traces are generated, which finally causes the deposited OLED film to be non-uniform. In addition, due to the fact that the base substrate is arranged on an open print platform and exposed to air, rates of evaporating respective ink droplets distributed on the base substrate may be different, which may generates oval mura on the base substrate where the ink droplets have been sprayed. Such mura as well as the border traces may adversely affect the luminance uniformity of the display device, and thereby degrade the display quality of the display device. Therefore, for most of the display devices, the luminance uniformity of the display device is directly affected by thickness uniformity of the film on the base substrate, while the uniformity of the film is directly affected by the uniformity of the densities of the ink droplets distributed on the base substrate.

For achieving a more uniform OLED film deposited on the base substrate, the present disclosure provides in some embodiments a method for forming a film, so as to improve the uniformity of the film which is adversely affected by the above time difference and the above atmosphere difference to some extent, and thus improve the display quality of the display device.

As shown in FIG. 3, the present disclosure provides in some embodiments a method for forming a film including:

101: forming ink droplets on a base substrate, wherein each of the ink droplets includes a first solvent and a film material dissolved in the first solvent;

102: subjecting the ink droplets on the base substrate to a solvent homogenizing distribution process; and

103: evaporating the first solvent in the ink droplets to form the film after the ink droplets have been subjected to the solvent homogenizing distribution process.

In particular, the above film forming method may be applied in the IJP technique.

In particular, in step 101, the ink droplets are formed on the base substrate after the ink jet printer has printed on the whole base substrate. The ink droplets formed on the base substrate includes a film material and a first solvent, e.g. including one or more organic compounds such as ethylene glycol, glycerol, toluene, mesitylene, anisole methoxybenzene and cyclohexylbenzene. For example, a material for the OLED function layer may be dissolved as a solution in the first solvent, so as to obtain the ink for the IJP Thus, when the ink droplets have been sprayed on the base substrate by the ink jet printer, the OLED film may be formed on the base substrate by the material for the OLED function layer included in the ink droplets.

Then, as shown in step 102, the ink droplets formed on the base substrate 101 in step 101 are subjected to a solvent homogenizing distribution process, so that the densities of the ink droplets distributed on the base substrate tend to be uniform.

In particular, the base substrate may be placed into the sealable solvent bin, so as to prevent the densities of the ink droplets formed on the base substrate in step 101 from being different. In the sealed solvent bin, gas molecules will be in perpetual and random motion at different speeds in all directions according to the theory of molecular motion. Thus, molecules of the first solvent volatilized from the ink droplets are in the molecular motion within the solvent bin, and ink droplet atmospheres distributed within the solvent bin will be same after a certain time, so that the densities of the ink droplets distributed on the base substrate tends to be same, and thus the ink droplets are distributed uniformly on the whole base substrate.

For example, the ink droplets are formed on the base substrate by two printing processes, where the ink droplets are formed in a first region of the base substrate in the first printing process, and then the ink droplets are formed in a second region of the base substrate in the second printing process. It is assumed that a density of the ink droplets for printing is 60%. The first solvent in the ink droplets firstly formed in the first region will be in volatilization before the ink droplets are formed in the second region, and thus upon the ink droplets have been formed in the second region, the density of the ink droplets in the first region may increased to be 80% while the density of the ink droplets in the second region is still 60%. At this point, the base substrate is placed into the solvent bin and then the solvent bin is sealed. Due to the higher density of the ink droplets in the first region, a volatizing rate of the ink droplets in the first region will be slower than that of the ink droplets in the second region. As a result, a portion of the molecules of the first solvent volatized from the ink droplets in the second region may move into the ink droplets in the first region, and thus finally the density of the ink droplets in the first region tends to be same as that of the ink droplets in the second region, e.g. 70%.

Further, the solvent bin may be heated to enable the molecules of the first solvent in the solvent bin to move faster, so that the atmospheres of the ink droplets distributed on the base substrate in the solvent bin will be same, and finally the densities of the ink droplets distributed on the whole base substrate will be uniform.

There are some other methods for subjecting the ink droplets formed on the base substrate in step 101 to a solvent homogenizing distribution process, which will be described in details in subsequent embodiments.

In step 103, after the ink droplets have been subjected to the solvent homogenizing distribution process in step 102, the base substrate may be subjected to processes such as drying and baking, so as to evaporate the first solvent in the ink droplets on the base substrate and deposit the film on the base substrate by the film material.

In particular, the base substrate may be placed into a device such as a drying device or a baking device to dry and bake the base substrate, so as to evaporate the first solvent in the ink droplets on the base substrate. Alternatively, the base substrate may be placed in the natural environment to dry the base substrate naturally, so as to evaporate the first solvent in the ink droplets on the base substrate.

The present disclosure provides in some embodiments a method for forming a film, wherein ink droplets are formed on a base substrate, and then the ink droplets on the base substrate are subjected to a solvent homogenizing distribution process, so that densities of the ink droplets distributed on the base substrate tends to be uniform. Further, when a first solvent in the ink droplets are evaporated, a film with a more uniform thickness may be formed due to the uniformity of the densities of the ink droplets distributed on the base substrate. As a result, it is at least partially prevented the border traces on the base substrate that were generated in the printing process due to the printing time difference and the ink droplets atmosphere difference in the related art from being generated, so as to improve the uniformity of the film, and thus improve the display quality of the display device.

### Embodiment 2

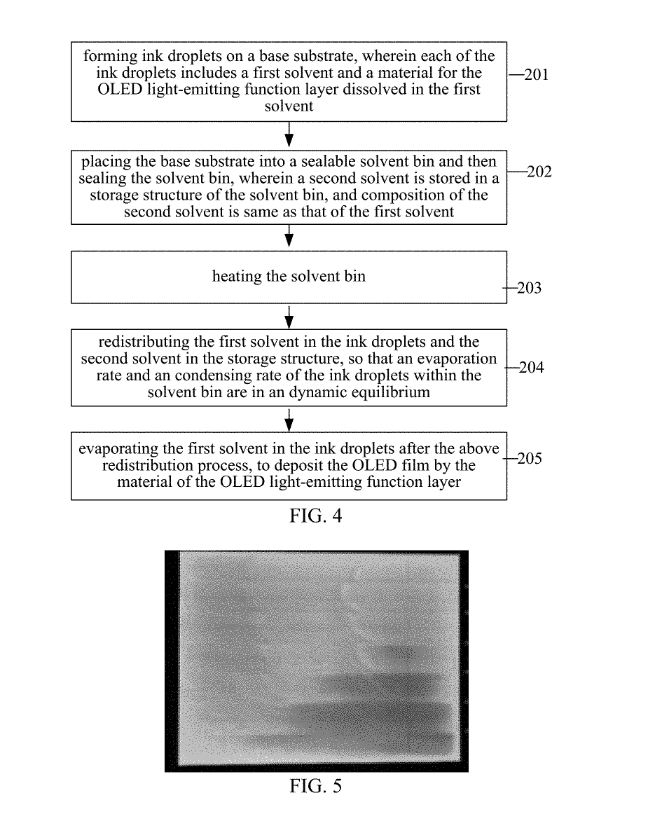

As shown in FIG. 4, the present disclosure provides in some embodiments a method for forming a film, and for example, in the case that a film material is a material for an OLED function layer, the method includes:

201: forming ink droplets on a base substrate, wherein each of the ink droplets includes a first solvent and a material for the OLED function layer dissolved in the first solvent;

202: placing the base substrate into a sealable solvent bin and then sealing the solvent bin, wherein a second solvent is stored in a storage structure of the solvent bin, and composition of the second solvent is same as that of the first solvent;

203: heating the solvent bin;

204: redistributing the first solvent in the ink droplets and the second solvent in the storage structure, so that an evaporation rate and an condensing rate of the ink droplets within the solvent bin are in an dynamic equilibrium; and

205: evaporating the first solvent in the ink droplets after the above redistribution process, so as to deposit the OLED film by the material of the OLED function layer.

In step 201, the ink droplets are formed on the base substrate after the ink jet printer has printed on the whole base substrate.

The ink droplets formed on the base substrate includes the material for the OLED function layer and the first solvent. In particular, the material for the OLED function layer may be dissolved as a solution in the first solvent, so as to obtain the ink droplets for the ink jet printer. Thus, when the ink droplets have been sprayed on the base substrate by the ink jet printer, the OLED film may be formed on the base substrate by the material for the OLED function layer included in the ink droplets.

In step 202, the base substrate may be placed into the sealable solvent bin to improve the uniformity of the densities of the ink droplets distributed on the base substrate. The solvent bin may include the storage structure, e.g. a sponge ribbon with a supporting mechanism. The storage structure is arranged above the base substrate and not in contact with the base substrate.

In particular, the storage structure stores the second solvent which is of composition same as that of the first solvent. Thus, similarly as the first solvent, the second solvent in the storage structure may be volatized a lot, so that the second solvent in a gaseous state is distributed uniformly in the solvent bin. The molecules of the volatized second solvent and the molecules of the first solvent volatized from the base substrate may be fully mixed, so that a uniform ink droplet atmosphere is formed in the solvent bin.

It should be noted that, the first solvent may be a single solvent consisting of ethylene glycol, glycerol, toluene, mesitylene, anisole methoxybenzene or cyclohexylbenzene, or a mixed solvent consisting of two or more of ethylene glycol, glycerol, toluene, mesitylene, anisole methoxybenzene and cyclohexylbenzene. In the case that the first solvent is the mixed solvent, the second solvent includes any one or more of the components of the first solvent.

The storage structure may be not arranged in the solvent bin; instead, the second solvent in the gaseous state is distributed uniformly in the solvent bin. In addition, a solvent injection member, e.g. a solvent injection hole may be arranged on the storage structure. Thus, the second solvent may be added into the storage structure by the solvent injection hole at any time.

In step 203, after the base substrate is placed into the sealable solvent bin and then the solvent bin is sealed, the solvent bin may be heated by the OLED film forming device, so as to accelerate the molecular motion within the solvent bin. The molecules of the second solvent and the first solvent in the gaseous state are distributed uniformly in the solvent bin, thereby these molecules are accelerated to move towards a region with a large evaporation amount on the base substrate. Finally a saturated vapor pressure is achieved in the solvent bin, so that it is assured that the atmospheres of the ink droplets distributed on the base substrate in the solvent bin are same, and finally the densities of the ink droplets distributed on the whole base substrate are kept to be uniform.

The temperature for heating the solvent bin has a relationship with the saturated vapor pressure achieved in the solvent bin by the first solvent and the second solvent. In other words, the solvent bin is heated at such a temperature that a saturated vapor pressure may be achieved in the solvent bin by the first solvent and the second solvent. Optionally, the temperature for heating the solvent may be in the range of from 20° C. to 150° C.

In the step 204, the storage structure of the solvent bin includes the second solvent, and it is redistributed the first solvent in the ink droplets on the base substrate within the solvent bin and the second solvent volatilized from the storage structure by the heating process in step 203, so that an evaporation rate and an condensing rate of the ink droplets within the solvent bin are in an dynamic equilibrium. As a result, the ink droplets within the whole solvent bin are under the saturated vapor pressure, which may accelerate the process of uniform the densities of the ink droplets distributed on the base substrate.

For example, in the above step 102, the density of the ink droplets in the first region is 80% while the density of the ink droplets in the second region is 60% before the base substrate is placed into the sealable solvent bin. After the base substrate is placed into the solvent bin and the solvent bin is sealed, the second solvent included in the storage structure of the solvent bin will be in the gaseous state and distributed uniformly in the solvent bin. Composition of the second solvent is same as that of the first solvent. The molecules of the first solvent and the molecules of the second solvent are fully mixed, and then moves to the ink droplets in the first and second regions, and finally the evaporation rate and the condensing rate of the ink droplets within the solvent bin are in the dynamic equilibrium, so that the density of the ink droplets in the first region and the density of the ink droplets in the second region tends to be same.

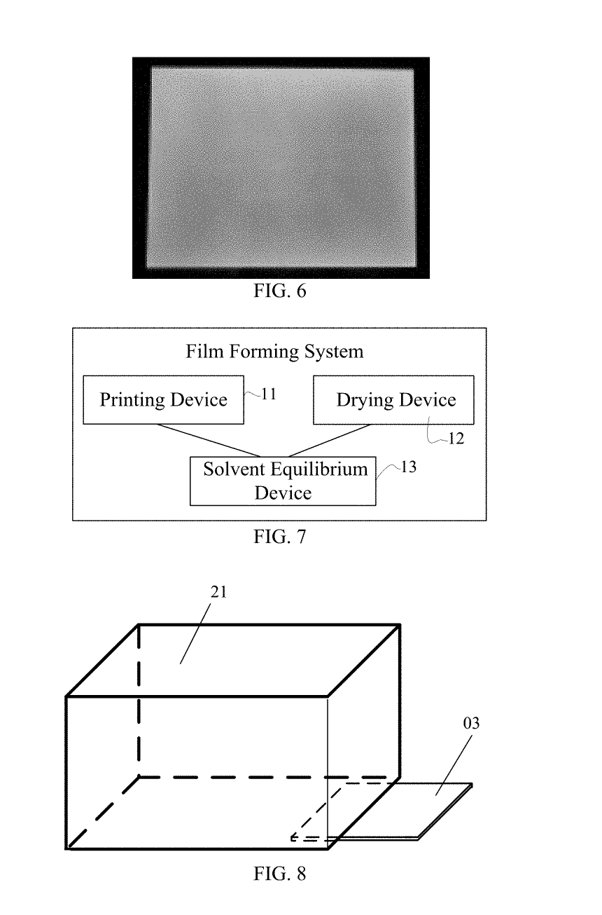

Therefore, after the steps 203 and 204, the ink droplets formed on the base substrate are subjected to the homogenizing distribution process in the solvent bin, so that the densities of the ink droplets distributed on the base substrate are more uniform. As shown in FIG. 5, it is a schematic view showing ink droplets distributed on the base substrate and not subjected to a solvent homogenizing distribution process in the related art. As shown in FIG. 6, it is a schematic view showing ink droplets distributed on the base substrate under a same condition in the film forming method according to an embodiment of the present disclosure; Obviously, on the base substrate of FIG. 5, the border traces are generated at adjacent printing positions due to the time difference of volatizing the ink droplets and the atmosphere difference of the ink droplets sprayed every time. In contrast, on the base substrate of FIG. 6, the densities of the ink droplets subjected to the homogenizing distribution process are more uniform, so that the resultant OLED film is more uniform.

In addition, it should be noted that a sequence of the steps 203 and 204 are not particularly defined herein, which may be executed simultaneously.

In step 205, after the ink droplets have been subjected to the solvent homogenizing distribution process in steps 202-204, the base substrate may be subjected to processes such as drying and baking, so as to volatize the first solvent in the ink droplets on the base substrate and deposit the OLED film on the base substrate by the material for the OLED function layer. The OLED film may include one or more of a hole transport layer, an organic light-emitting layer, a hole injection layer, an electron injection layer and an electron transport layer for the OLED device.

The present disclosure provides in some embodiments a method for forming a film, wherein ink droplets are formed on a base substrate, and then the ink droplets on the base substrate are subjected to a solvent homogenizing distribution process, so that densities of the ink droplets distributed on the base substrate tends to be uniform. Further, when a first solvent in the ink droplets are evaporated, a film with a more uniform thickness may be formed due to the uniformity of the densities of the ink droplets distributed on the base substrate. As a result, it is at least partially prevented the border traces on the base substrate, which may be generated in the printing process due to the printing time difference and the ink droplets atmosphere difference in the related art, from being generated, so as to improve the uniformity of the film, and thus improve the display quality of the display device.

### Embodiment 3

As illustrated in FIG. 7, the present disclosure provides in some embodiments a system for forming a film, including a printing device 11, a drying device 12 and a solvent equilibrium device 13. The printing device 11 is configured to form ink droplets on a base substrate, where each of the ink droplets includes a first solvent and a film material dissolved in the first solvent. The solvent equilibrium device 13 is configured to subject the ink droplets to a solvent homogenizing distribution process. The drying device 12 is configured to evaporate the first solvent in the ink droplets to form the film after the ink droplets have been subjected to the solvent homogenizing distribution process.

For example, as shown in FIG. 8, the solvent equilibrium device 13 includes a solvent bin 21 that is of a sealable structure, the base substrate 03 on which the ink droplets are formed are placed into the solvent bin 21 and then the solvent bin 21 is sealed, so as to isolate the base substrate 03 from the outside.

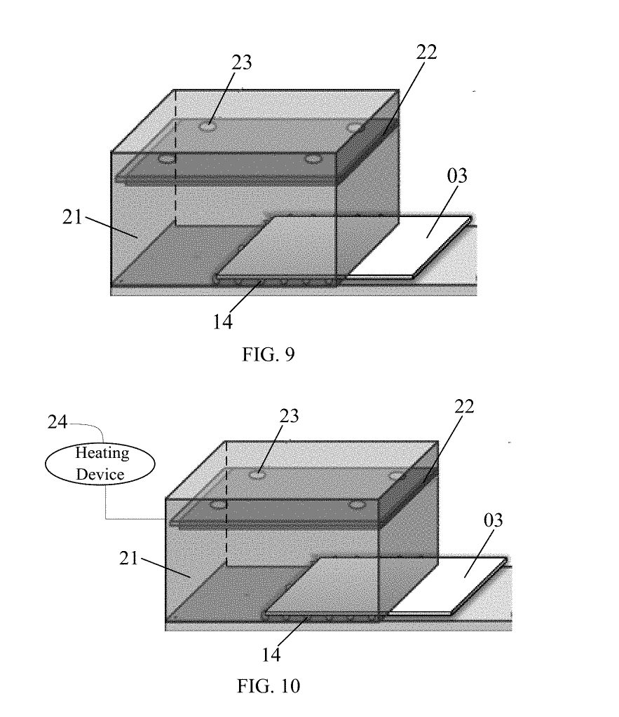

Further, as shown in FIG. 9, the solvent bin 21 includes a storage structure 22 such as a sponge structure, the storage structure 22 is configured to store the second solvent, and composition of the second solvent is same as that of the first solvent.

In addition, a solvent injection structure is arranged on the storage structure. As shown in FIG. 9, the solvent injection structure may be a solvent injection hole 23 configured to inject the second solvent.

Further, as shown in FIG. 10, the system further includes a heating device 24 configured to heat the solvent bin 21.

Further, as shown in FIG. 9 or 10, the system may further includes a transport device 14, e.g. a wheel or a gear, and the transport device 14 is configured to transport the base substrate 03 on which the ink droplets are formed in the printing device 11 into the solvent bin 21.

The present disclosure provides in some embodiments a system for forming a film, wherein ink droplets are formed on a base substrate, and then the ink droplets on the base substrate are subjected to a solvent homogenizing distribution process, so that densities of the ink droplets distributed on the base substrate tends to be uniform. Further, when a first solvent in the ink droplets are evaporated, a film with a more uniform thickness may be formed due to the uniformity of the densities of the ink droplets distributed on the base substrate. As a result, it is at least partially prevented the border traces on the base substrate, which may be generated in the printing process due to the printing time difference and the ink droplets atmosphere difference in the related art, from being generated, so as to improve the uniformity of the film, and thus improve the display quality of the display device.

In the description of the present disclosure, particular features, structures or materials may be combined in a suitable manner in one or more embodiments.

The above are merely embodiments of the present disclosure and shall not be used to limit the scope of the present disclosure. It should be noted that, a person skilled in the art may make improvements and modifications without departing from the principle of the present disclosure, and these improvements and modifications shall also fall within the scope of the present disclosure. Thus, a scope of the present disclosure is confined in claims.

1. A method for forming a film, comprising:
forming ink droplets on a base substrate, wherein each of the ink droplets comprises a first solvent and a film material dissolved in the first solvent;
subjecting the ink droplets to a solvent homogenizing distribution process; and
evaporating the first solvent in the ink droplets to form the film after the ink droplets have been subjected to the solvent homogenizing distribution process.

2. The method according to claim 1, wherein the film comprises one or more of a hole transport layer, an organic light-emitting layer, a hole injection layer, an electron injection layer and an electron transport layer for an organic light-emitting diode (OLED).

3. The method according to claim 1, wherein the step of subjecting the ink droplets to the solvent homogenizing distribution process comprises:
placing the base substrate on which the ink droplets are formed into a solvent bin, wherein the solvent bin is of a sealable structure.

4. The method according to claim 3, wherein a second solvent in a gaseous state is distributed uniformly in the solvent bin, and
composition of the second solvent is same as that of the first solvent, or
in the case that the first solvent comprises two or more components, the second solvent comprises any one or more of the components of the first solvent.

5. The method according to claim 4, wherein the solvent bin comprises a storage structure configured to store the second solvent.

6. The method according to claim 3, wherein after the step of placing the base substrate on which the ink droplets are formed into the solvent bin, the method further comprises:
heating the solvent bin.

7. The method according to claim 6, wherein the solvent bin is heated at such a temperature that a saturated vapor pressure is achieved in the solvent bin by the first solvent and the second solvent.

8. A system for forming a film, comprising a printing device, a drying device and a solvent equilibrium device, wherein
the printing device is configured to form ink droplets on a base substrate, wherein each of the ink droplets comprises a first solvent and a film material dissolved in the first solvent;
the solvent equilibrium device is configured to subject the ink droplets to a solvent homogenizing distribution process; and
the drying device is configured to evaporate the first solvent in the ink droplets to form the film after the ink droplets have been subjected to the solvent homogenizing distribution process.

9. The system according to claim 8, wherein the solvent equilibrium device comprises a solvent bin,
the solvent bin is of a sealable structure, and configured to accommodate the base substrate on which the ink droplets are formed, and isolate the base substrate from the outside.

10. The system according to claim 9, wherein the solvent bin comprises a storage structure configured to store a second solvent, and
composition of the second solvent is same as that of the first solvent, or in the case that the first solvent comprises two or more components, the second solvent comprises any one or more of the components of the first solvent.

11. The system according to claim 10, wherein the storage structure is arranged above the base substrate and not in contact with the base substrate.

12. The system according to claim 10, wherein a solvent injection member is arranged on the storage structure, and configured to inject the second solvent into the storage structure.

13. The system according to claim 8, further comprising a heating device configured to heat the solvent bin.

14. The system according to claim 8, further comprising a transport device configured to transport the base substrate on which the ink droplets are formed into the solvent bin.

15. The method according to claim 4, wherein after the step of placing the base substrate on which the ink droplets are formed into the solvent bin, the method further comprises:
heating the solvent bin.

16. The method according to claim 5, wherein after the step of placing the base substrate on which the ink droplets are formed into the solvent bin, the method further comprises:
heating the solvent bin.

17. The system according to claim 9, further comprising a heating device configured to heat the solvent bin.

18. The system according to claim 9, further comprising a transport device configured to transport the base substrate on which the ink droplets are formed into the solvent bin.

19. The system according to claim 10, further comprising a heating device configured to heat the solvent bin.

20. The system according to claim 10, further comprising a transport device configured to transport the base substrate on which the ink droplets are formed into the solvent bin.
